(19) United States
(12) Patent Application Publication
(10) Pub. No.: US 2016/0276450 A1
(43) Pub. Date: Sep. 22, 2016

(54) SEMICONDUCTOR DEVICE

(71) Applicant: KABUSHIKI KAISHA TOSHIBA, Tokyo (JP)

(72) Inventor: Masakazu KOBAYASHI, Kanazawa Ishikawa (JP)

(21) Appl. No.: 14/837,929

(22) Filed: Aug. 27, 2015

(30) Foreign Application Priority Data
Mar. 16, 2015 (JP) 2015-052247

(51) Int. Cl. H01L 29/423; H01L 29/04; H01L 29/78; H01L 21/285; H01L 29/66; H01L 29/49; H01L 21/28; H01L 29/06; H01L 29/739

(52) U.S. Cl. CPC H01L 29/4236; H01L 29/0684; H01L 29/045; H01L 29/42376; H01L 29/42364; H01L 29/7813; H01L 29/7397; H01L 29/66734; H01L 29/66348; H01L 29/4916; H01L 21/28035; H01L 21/28525; H01L 21/28556

(57) ABSTRACT

A semiconductor device includes a first semiconductor region of a first conductivity type and a second semiconductor region of a second conductivity type adjacent to the first semiconductor region in a first direction. A third semiconductor region of the first conductivity type is disposed on the second semiconductor region and separated from the first semiconductor region in the first direction by the second semiconductor region. A gate electrode is adjacent to the first, second, and third semiconductor regions. A gap is disposed between the gate electrode and the first semiconductor region.

### CROSS-REFERENCE TO RELATED APPLICATION

This application is based upon and claims the benefit of priority from Japanese Patent Application No. 2015-052247, filed Mar. 16, 2015, the entire contents of which are incorporated herein by reference.

### FIELD

Embodiments described herein relate generally to a semiconductor device.

### BACKGROUND

As a semiconductor device, there is a metal oxide semiconductor field effect transistor (MOSFET), an insulated gate bipolar transistor (IGBT), or the like. In these semiconductor devices, by applying a voltage to a gate electrode, and forming a channel (inversion region) in a semiconductor region in the vicinity of a gate insulating layer, the semiconductor device is placed in an ON state (conducting state). If the voltage is applied to the gate electrode, an electrical field is generated in the gate insulating layer. If the gate insulating layer locally includes a portion having a small film thickness, the strength of the electrical field becomes large in that portion, and the gate insulating layer may be broken.

### DESCRIPTION OF THE DRAWINGS

FIG. 1 is a perspective cross-sectional view illustrating a portion of a semiconductor device according to a first embodiment.

FIG. 2 is an enlarged cross-sectional view illustrating a portion of the semiconductor device according to the first embodiment.

FIG. 3A and FIG. 3B to FIG. 8A and FIG. 8B are cross-sectional views illustrating a manufacturing process of the semiconductor device according to the first embodiment.

FIG. 9 is a perspective cross-sectional view illustrating a portion of a semiconductor device according to a modification of the first embodiment.

FIG. 10 is a perspective cross-sectional view illustrating a portion of a semiconductor device according to a second embodiment.

FIG. 11 is an enlarged cross-sectional view illustrating a portion of the semiconductor device according to the second embodiment.

### DETAILED DESCRIPTION

In general, according to an embodiment, a semiconductor device includes a first semiconductor region of a first conductivity type (e.g., n-type) and a second semiconductor region of a second conductivity type (e.g., p-type) adjacent to the first semiconductor region in a first direction (e.g., a vertical/stacking direction). A third semiconductor region of the first conductivity type is disposed on the second semiconductor region and is separated from the first semiconductor region in the first direction by the second semiconductor region. A gate electrode is adjacent to the first, second, and third semiconductor regions. A gap is present between the gate electrode and the first semiconductor region. In this context, a “gap” refers to a space or volume in which a conductive material of the gate electrode, semiconducting material of the semiconducting regions, and an insulating material of various deposited insulating layers is not present. The gap may be referred to in some contexts as a void, or an unfilled cavity.

In general, according to another embodiment, a semiconductor device includes a first semiconductor region of a first conductivity type, a second semiconductor region of a second conductivity type, a third semiconductor region of the first conductivity type, a gate electrode, and a first insulating layer. The second semiconductor region is provided on the first semiconductor region. The third semiconductor region is provided on the second semiconductor region. The first insulating layer is provided between the gate electrode, the first semiconductor region, the second semiconductor region, and the third semiconductor region. The first insulating layer includes a first insulating portion, and a second insulating portion. The first insulating portion is provided along a second direction perpendicular to a first direction from the first semiconductor region toward the second semiconductor region. The first insulating portion is positioned between the first semiconductor region and the gate electrode in the first direction. The second insulating portion is provided along a direction inclined with respect to the first direction and the second direction. The second insulating portion is positioned between the first semiconductor region and the gate electrode. A gap is provided between the second insulating portion and the gate electrode. A thickness of the second insulating portion is smaller than that of the first insulating portion.

Hereinafter, embodiments will be described with reference to the drawings.

Furthermore, the drawings are schematic or conceptual drawings. A relationship between a thickness and a width of each element, or a ratio of sizes between the elements, is not necessarily limited to those depicted. Moreover, even if the same element is illustrated in different drawings, the same element may be illustrated in the different drawings such that the mutual dimension and ratio are different from each other.

Additionally, in the specification and each drawing, the same reference numeral are attached to the same elements as the components which are previously described, and the detailed description thereof will be appropriately omitted.

In the description of each embodiment, an XYZ orthogonal coordinate system is used. Two directions which are orthogonal to each other in a direction parallel to a main surface of a semiconductor layer S, are referred to as an X direction (second direction) and a Y direction, and a direction which is orthogonal to both of the X direction and the Y direction, is referred to as a Z direction (first direction).

Regarding the embodiments which will be described below, each embodiment may be modified by reversing a p-type and an n-type of each semiconductor region.

### First Embodiment

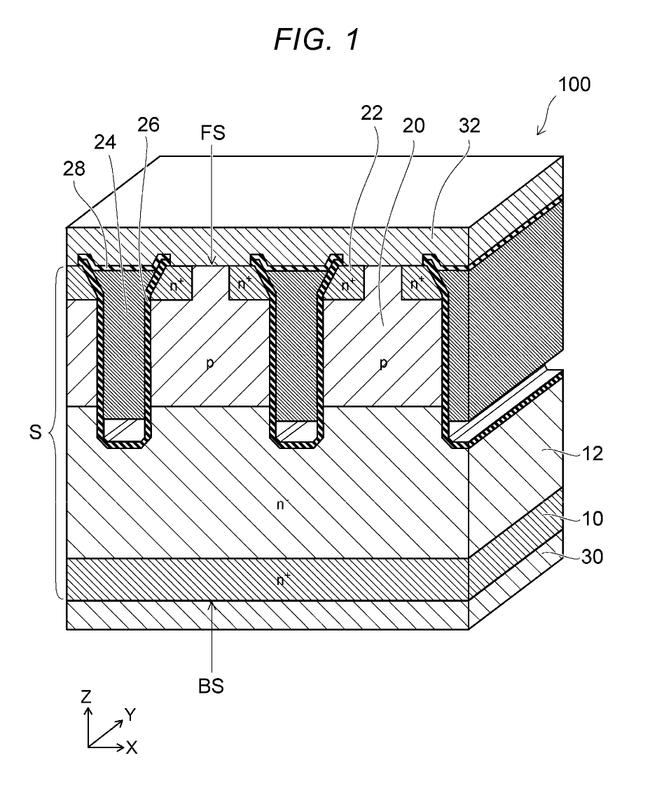

FIG. 1 is a perspective cross-sectional view illustrating a portion of a semiconductor device 100 according to a first embodiment.

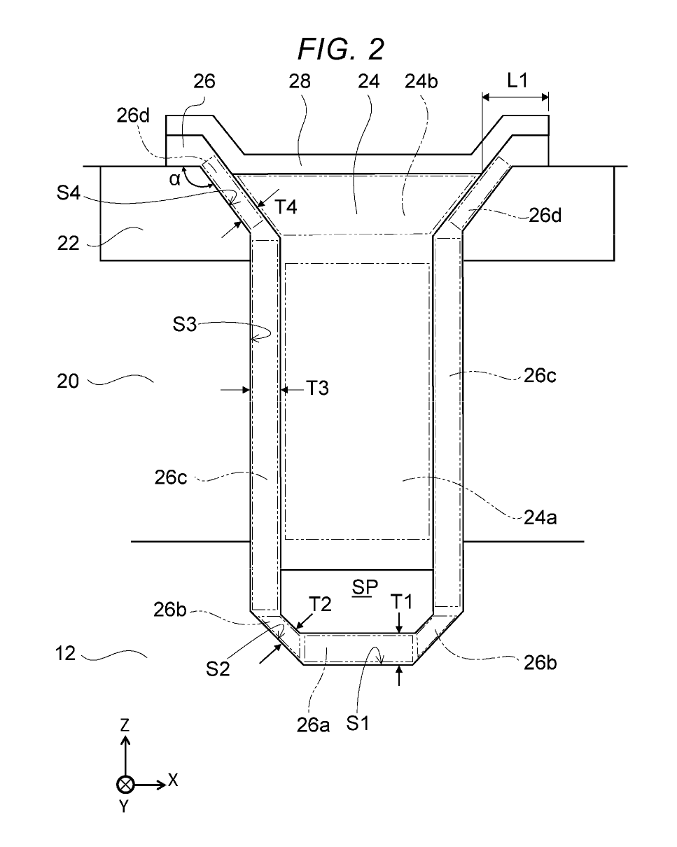

FIG. 2 is an enlarged cross-sectional view illustrating a portion of the semiconductor device 100 according to the first embodiment.

For example, the semiconductor device 100 according to the first embodiment is a MOSFET.

The semiconductor device 100 according to the first embodiment, includes a semiconductor layer, a gate electrode 24, a gate insulating layer 26 (first insulation layer), an insulating layer 28 (second insulating layer), a source electrode 32 (first electrode), and a drain electrode 30.

The semiconductor layer includes an n⁺ type drain region 10, a semiconductor region 12 (first semiconductor region) of an n⁻ type, a base region 20 (second semiconductor region) of a p-type, and an n⁺ type source region 22 (third semiconductor region). In the description of specific examples, n-type layers/regions may be referred to as first conductivity type layers/regions and p-type layers/regions may be referred to as second conductivity type layers/regions; however, as noted above, the specific conductivity type of layers/regions may be reversed in some embodiments such that the first conductivity type layers/regions are p-type layers/regions and the second conductivity type layers/regions are n-type layers/regions.

The semiconductor layer S includes a front surface FS and a back surface BS. The drain electrode 30 is arranged on the back surface BS, and the source electrode 31 is arranged on the front surface FS.

The n⁺ type drain region 10 is arranged on the back surface BS of the semiconductor layer S, and is electrically connected to the drain electrode 30.

The n⁻ type semiconductor region 12 is arranged on the n⁺ type drain region 10.

The p-type base region 20 is selectively arranged on the n⁻ type semiconductor region 12. A plurality of p-type base regions 20 are arranged in the X direction, and each of the p-type base regions 20 extends in the Y direction.

The n⁺ type source region 22 is selectively arranged on the p-type base region 20. A plurality of n⁺ type source regions 22 are arranged in the X direction, and each of the n⁺ type source regions 22 extends in the Y direction.

The gate electrode 24 is adjacent to a portion of the n⁻ type semiconductor region 12, and at least a portion of the p-type base region 20 and the n⁺ type source region 22. Between the gate electrode 24 and the semiconductor regions, the gate insulating layer 26 is arranged.

A plurality of gate electrodes 24 are arranged in the X direction, and each of the gate electrodes 24 extends in the Y direction. As depicted in FIG. 1, the gate electrodes in some embodiments can be trench electrodes extending in the z-direction into the semiconductor layer S.

The source electrode 32 is arranged on the front surface FS, and is electrically connected to the n⁺ type source region 22. On the gate electrode 24, the insulating layer 28 is arranged, and the source electrode 32 is electrically separated from the gate electrode 24 by the insulating layer 28.

In a state where a positive voltage is applied to the drain electrode 30 and the source electrode 32, if the voltage of a threshold voltage or more is applied to the gate electrode 24, the MOSFET is in an ON state. At this time, a channel is formed in the vicinity of the gate insulating layer 26 in the p-type base region 20.

Next, for this first embodiment, specific structures of the gate electrode 24 and the gate insulating layer 26 will be described with reference to FIG. 2.

As illustrated in FIG. 2, the gate electrode 24 includes a first electrode portion 24a and a second electrode portion 24b.

The first electrode portion 24a faces the p-type base region 20 in the X direction. The second electrode portion 24b faces the n⁺ type source region 22 in the X direction.

A length of the second electrode portion 24b in the X direction is longer than a length of the first electrode portion 24a in the X direction.

The gate insulating layer 26 includes a first insulating portion 26a, a second insulating portion 26b, a third insulating portion 26c, and a fourth insulating portion 26d.

The first insulating portion 26a is arranged between the gate electrode 24 and the n⁻ type semiconductor region 12, in the Z direction. The first insulating portion 26a extends along the X direction.

The second insulating portion 26b is arranged between the gate electrode 24 and the n⁻ type semiconductor region 12. The second insulating portion 26b extends in the Y direction, and is arranged along a direction inclined to the X direction and the Z direction.

At least a portion of the third insulating portion 26c is arranged along the first direction (Z direction) toward the p-type base region 20 from the n⁻ type semiconductor region 12. Moreover, the third insulating portion 26c is arranged between the p-type base region 20 and the first electrode portion 24a in the X direction. The second insulating portion 26b is positioned between the first insulating portion 26a and the third insulating portion 26c, among the gate insulating layer 26. In the example illustrated in FIG. 2, a portion of the first insulating portion 26a is arranged between the n⁺ type source region 22 and the gate electrode 24, in the X direction, when viewed along the Z-direction. That is, from a top-down perspective it would appear that a portion of the first insulating portion 26a is between the left-right portions of n⁺ type source region 22 adjacent to a gate electrode 24.

The fourth insulating portion 26d is arranged between the n⁺ type source region 22 and the second electrode portion 24b in the X direction. The fourth insulating portion 26d extends in the Y direction, and is arranged along a direction inclined to the X direction and the Z direction.

Between the first insulating portion 26a and the gate electrode 24, and between the second insulating portion 26b and the gate electrode 24, a gap SP is disposed. However, so long as the gap SP is arranged between the second insulating portion 26b and the gate electrode 24, the gate electrode 24 may be in contact with a portion of the first insulating portion 26a.

A crystal plane orientation of a first surface S1, which is in contact with the first insulating portion 26a of the n⁻ type semiconductor region 12, is, for example, (111). In this case, a crystal plane orientation of a third surface S3 which is in contact with the third insulating portion 26c of the p-type base region 20 is similarly (111).

A crystal plane orientation of a second surface S2, which is in contact with the second insulating portion 26b of the n⁻ type semiconductor region 12, and a crystal plane orientation of a fourth surface S4, which is in contact with the fourth insulating portion 26d of the n⁺ type source region 22, are, for example, (100).

Here, a film thickness T1 of the first insulating portion 26a and a film thickness T3 of the third insulating portion 26c are greater than a film thickness T2 of the second insulating portion 26b and a film thickness T4 of the fourth insulating portion 26d. The film thickness T3 may be equal to the film thickness T1, or may be different from the film thickness T1. Moreover, the film thickness T4 may be equal to the film thickness T2, or may be different from the film thickness T2.

Furthermore, the film thickness T1 is a thickness of the first insulating portion 26a, in a direction perpendicular to the first surface S1. Similarly, the film thickness T2 is a thickness of the second insulating portion 26b, in a direction perpendicular to the second surface S2. The film thickness T3 is a thickness of the third insulating portion 26c, in a direction perpendicular to the third surface S3. The film thickness T4 is a thickness of the fourth insulating portion 26d, in a direction perpendicular to the fourth surface S4.

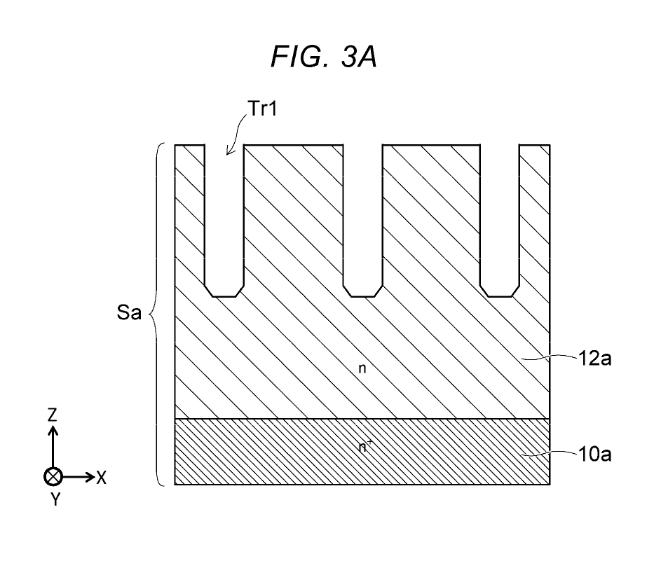

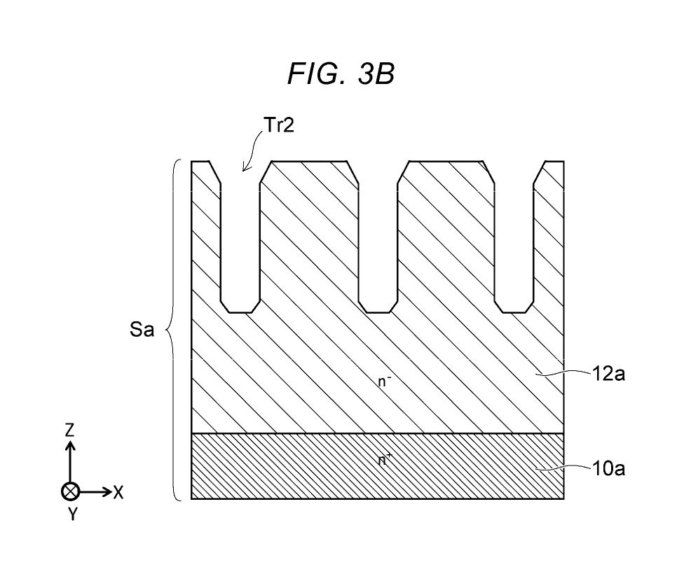

Next, an example of a method for manufacturing the semiconductor device 100, will be described with reference to FIG. 3A to FIG. 8B.

FIG. 3A to FIG. 8B are process cross-sectional views illustrating manufacturing processes of the semiconductor device 100 according to the first embodiment.

First, a semiconductor layer Sa, including an n⁺ type semiconductor region 10a and an n⁻ type semiconductor region 12a, is prepared. A main ingredient of the semiconductor layer Sa is silicon or a silicon carbide. On an n⁺ type Si substrate, by performing epitaxial growth of Si where n-type impurities are doped, the semiconductor layer Sa is formed. As an n-type impurity, phosphorus or arsenic may be used.

Next, as illustrated in FIG. 3A, a trench Tr1 is formed in the semiconductor layer Sa. The trench Tr1 is formed by using a photolithography method and a reactive ion etching (RIE) method.

Next, as illustrated in FIG. 3B, by etching the vicinity of an opening of the trench Tr1, a trench Tr2 is formed in such a manner that a taper in an upper portion is more gradual than the taper in a lower portion. That is, an inclination with respect to the Z direction in an upper portion of a side wall of the trench Tr2 is greater than an inclination with respect to the Z direction in a lower portion of the side wall of the trench Tr2. A dimension of the upper portion of the trench Tr2 in the X direction is greater than a dimension of the lower portion of the trench Tr2 in the X direction. The trench Tr2 is formed by using the photolithography method and the RIE method. At this time, an inner wall of the trench Tr2 includes the first surface S1 to the fourth surface S4.

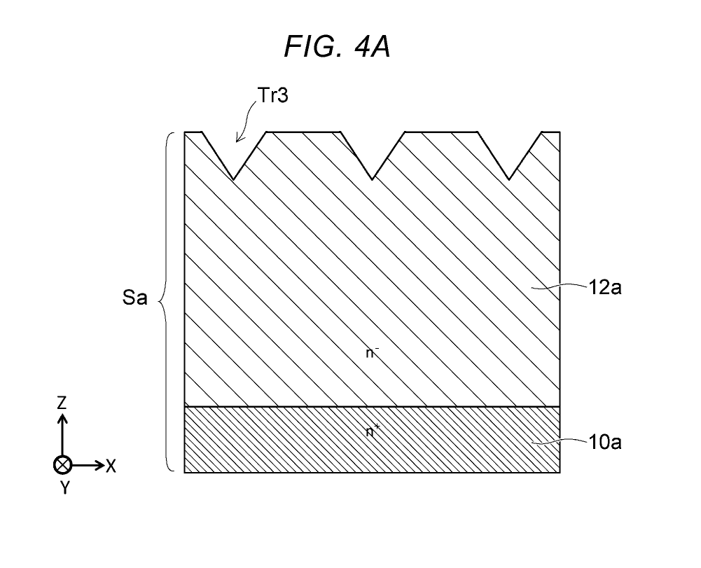

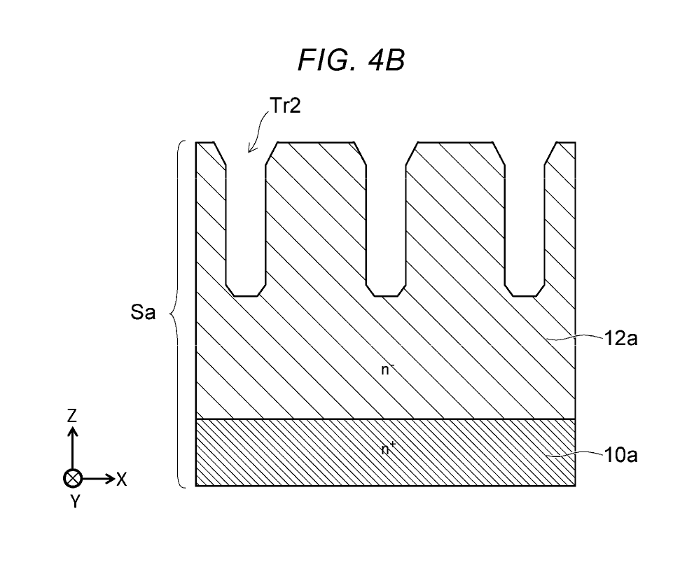

Alternatively, the processes illustrated in FIG. 4A and FIG. 4B may be performed instead of the processes illustrated in FIG. 3A and FIG. 3B.

First, as illustrated in FIG. 4A, a trench Tr3 is formed. A depth of the trench Tr3 is shallower than an ultimate depth of the trench Tr1.

Next, as illustrated in FIG. 4B, by further etching a portion of the trench Tr3, the trench Tr2 is formed to appear as in the result of the process illustrated in FIG. 3B.

Next, by performing ion implantation of p-type impurities into the surface of the semiconductor layer Sa, the p-type base region 20 is formed. Subsequently, by selectively performing the ion implantation of the n-type impurities into the p-type base region 20, the n⁺ type source region 22 is formed in a surface layer portion of the p-type base region 20. The p-type base region 20 is formed in the vicinity of a portion of the trench Tr2 so that a tip (opening) of the trench Tr2 is positioned in the n⁻ type semiconductor region 12. The n⁺ type source region 22 is formed in the vicinity of another portion of the trench Tr2. Among the semiconductor layer Sa, a portion of the region other than the p-type base region 20 and the n⁺ type source region 22, corresponds to the n⁻ type semiconductor region 12. As a p-type impurity, boron may be used.

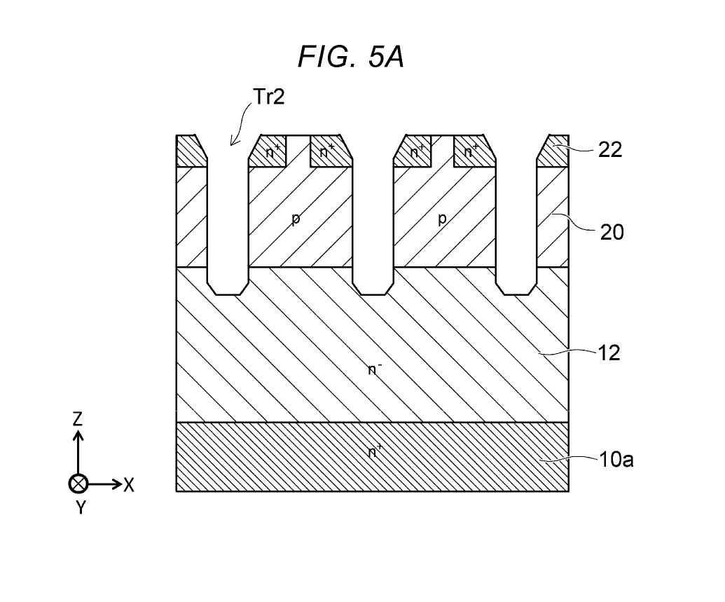

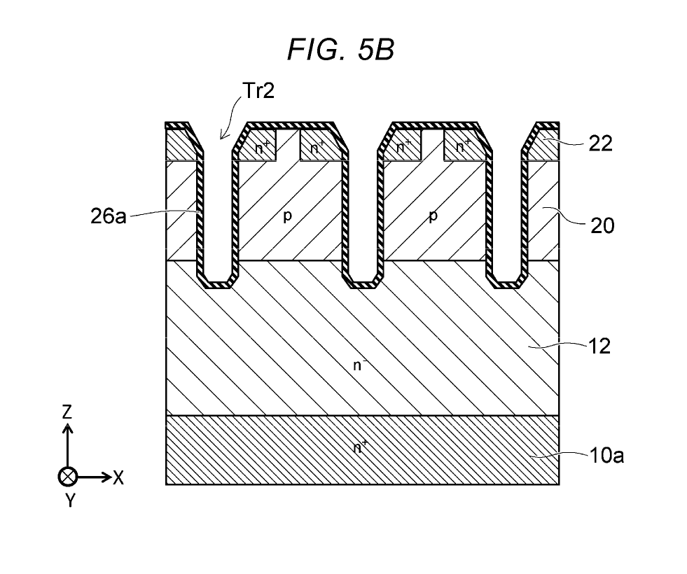

The state at this time is illustrated in FIG. 5A.

Furthermore, in alternative method, the p-type base region 20 and the n⁺ type source region 22 are first formed among the semiconductor layer Sa, and then the process illustrated in FIG. 3A and FIG. 3B, or the process illustrated in FIG. 4A and FIG. 4B may be performed, and the trench Tr2 may be formed. In this alternative case, the trench Tr2 is formed so as to pass through the p-type base region 20 and the n⁺ type source region 22, and to reach the n⁻ type semiconductor region 12, rather than forming n⁺ type source region 22 and p-type base region 20 after forming the Tr2.

Next, as illustrated in FIG. 5B, the gate insulating layer 26a is formed on the inner wall of the trench Tr2, the upper surface of the p-type base region 20, and the upper surface of the n⁺ type source region 22. In this embodiment, the gate insulating layer 26a includes a silicon oxide, and is formed by using a chemical vapor deposition (CVD) method. The gate insulating layer 26a may also be formed by performing thermal oxidation of the surface of the semiconductor layer Sa.

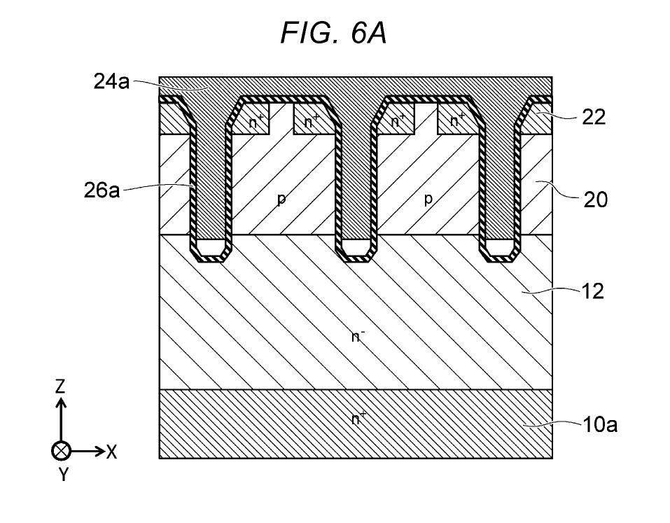

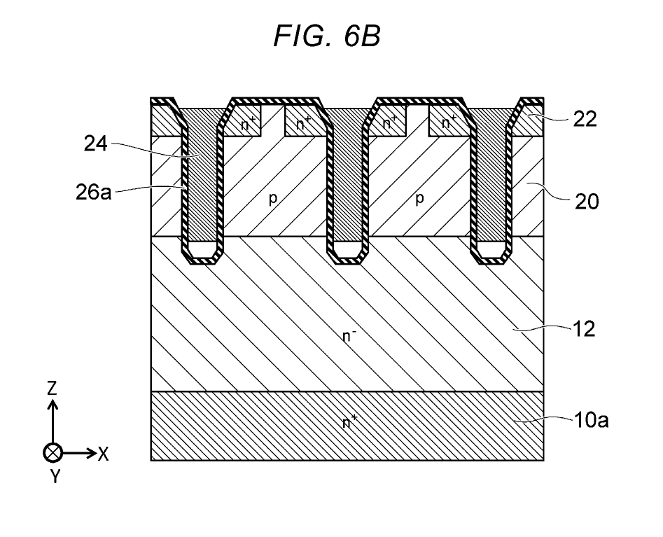

Next, the conductive layer 24a is formed on the gate insulating layer 26a. As illustrated in FIG. 6A, the conductive layer 24a is formed so that the conductive material is not deposited in a bottom portion of the trench Tr2. That is, the conductive layer 24a is formed so that the gap SP is formed in the bottom portion of the trench Tr2. For example, the conductive layer 24a may comprise a polycrystalline silicon that is formed by the CVD method and the CVD method can be performed in a condition where a film formation (deposition) speed is high. By performing the CVD method in this condition the film thus formed will attach to a portion of trench Tr2 where the taper angle is changed along the side wall of the trench Tr2. Effectively, the conductive material deposited in this condition will clog (fill) the opening of trench Tr2 before the conductive material is fully deposited on the lower surfaces of trench Tr2, and thus the gap SP will be formed.

Alternatively, by using the CVD method, the film formation is performed to such an extent that the opening of trench Tr2 is not clogged, and thereafter, by using an etching method such as the RIE method or an ion beam etching (IBE) method of which anisotropy is high, the conductive material which is deposited in the bottom portion of the trench Tr2 can be removed. After removing the conductive material which is deposited in the bottom portion of the trench Tr2, the deposition of the conductive material is performed again by the CVD method, and by clogging the opening of the trench Tr2, the conductive layer 24a and the gap SP are formed.

Next, as illustrated in FIG. 6B, a portion of the surface side of the conductive layer 24a is removed, and the gate electrode 24 is formed.

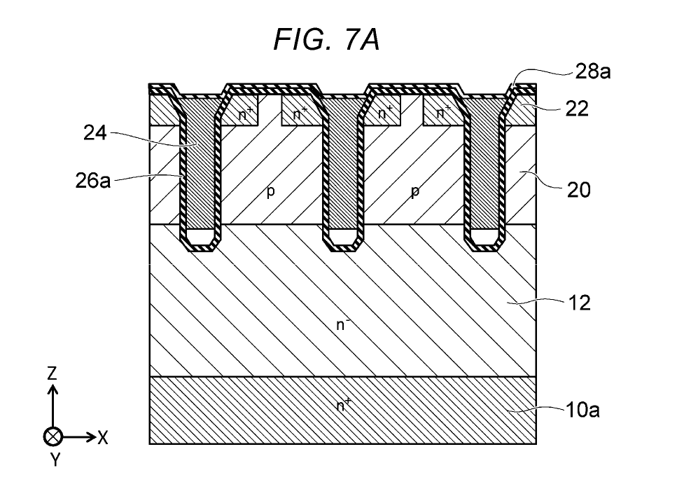

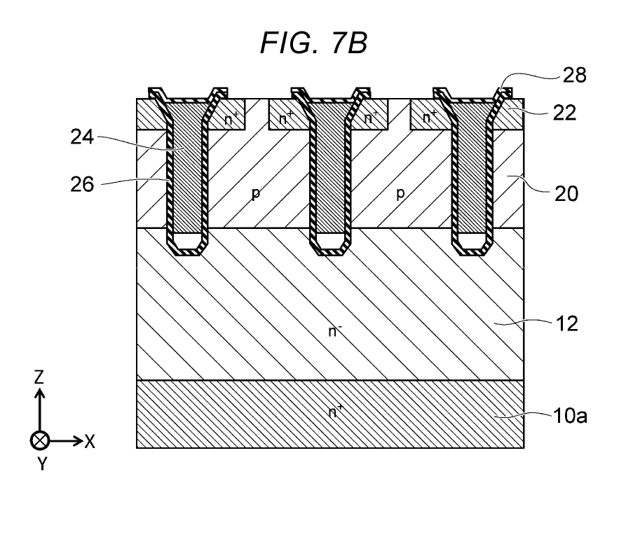

Next, as illustrated in FIG. 7A, an insulating layer 28a is formed on the gate electrode 24 and the gate insulating layer 26a. The insulating layer 28a, for example, includes a silicon oxide and is formed by using the CVD method.

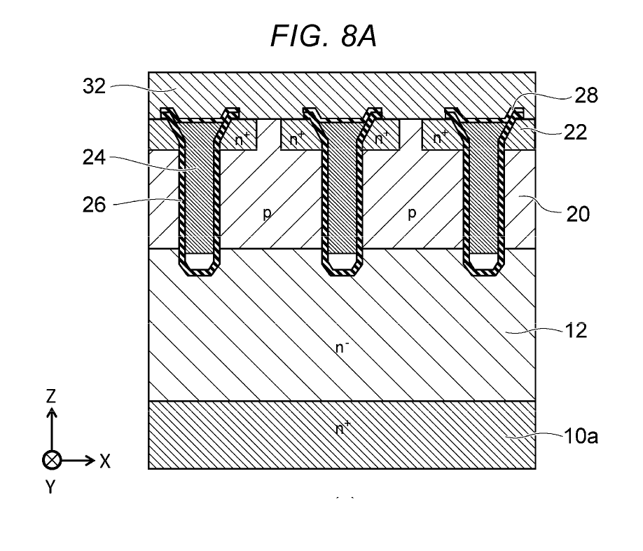

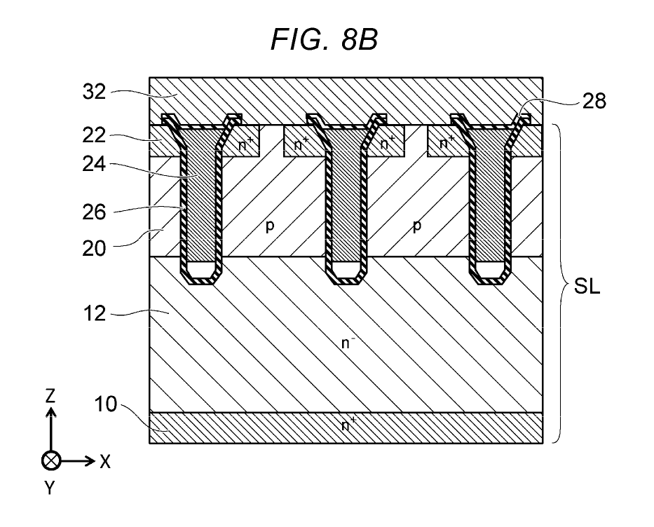

Next, as illustrated in FIG. 7B, by using the photolithography method and the RIE method, a portion of the gate insulating layer 26a and a portion of the insulating layer 28a are removed, and the n⁺ type source region 22 is exposed. Next, as illustrated in FIG. 8A, the source electrode 32 is formed on the p-type base region 20, on the n⁺ type source region 22, and on the insulating layer 28. The source electrode 32 can be formed by the CVD method, a physical vapor deposition (PVD) method, or a vapor deposition method.

Next, as illustrated in FIG. 8B, the back surface of the semiconductor layer Sa is polished until the thickness of the semiconductor layer Sa becomes a predetermined thickness, and the semiconductor layer S is formed. At this time, the back surface of the semiconductor layer Sa is polished so that a finish point of the polishing is in the n⁺ type semiconductor region 10a. By the process, the n⁺ type drain region 10 is formed.

Thereafter, the drain electrode 30 is formed on the back surface of the semiconductor layer S. The drain electrode 30 is formed by the same method as the source electrode 32.

By the above processes, the semiconductor device 100 illustrated in FIG. 1 and FIG. 2, is obtained.

Next, operations and effects according to the first embodiment will be described.

According to the first embodiment, when the voltage is applied to the gate electrode 24, it is possible to reduce a possibility of generating a breakdown in the gate insulating layer 26.

Among the gate insulation layer 26, the film thickness of the portion which is arranged at the angle to the trench bottom portion is apt to be smaller than the film thicknesses of other portions. The angle of the trench bottom portion is not formed into a right angle when the trench is formed. When the angle of the trench bottom portion which is formed in the semiconductor layer having the main ingredient of Si, is inclined to the trench bottom portion, a crystal plane orientation of the surface which is included in the angled portion is different from a crystal plane orientation of a bottom surface of the trench.

Specifically, for example, when the plane orientation of the angled portion is (100), the plane orientation of the bottom surface is (111) or (110). When the insulating layer is formed on the inner wall of the trench, the thickness of the film which is formed on the (100) surface, is apt to be smaller than the thickness of the film which is formed on the surface of another plane orientation such as (111) or (110).

Hence, when the gate electrode is embedded in the trench, and the voltage is applied to the gate insulating layer, an electrical field in the angled portion of which the film thickness is relatively small among the gate insulating layer, is greater than electrical fields in the other portions. Accordingly, in the angled portion, the possibility of generating a breakdown is higher than that in other portions.

In contrast thereto, in the first embodiment, the gap SP is arranged between the second insulating portion 26b and the gate electrode 24. Hence, when the voltage is applied to the gate electrode 24, the strength of the electrical field at the second insulating portion 26b is reduced in comparison with a case where no gap is between the second insulating portion 26b and the gate electrode 24. As a result, the possibility of generating the breakdown at the second insulating portions 26b is reduced.

Moreover, according to the first embodiment, since the strength of the electrical field in the second insulating portion 26b is reduced, it is possible to enhance a breakdown voltage of the gate electrode 24. Here, the breakdown voltage means a voltage of the case where the breakdown of the gate electrode 24 or the gate insulating layer 26 is generated.

In the manufacturing process of the semiconductor device 100, if variation is generated in the length of the gate electrode 24 in the Z direction, or a shape of the trench, a position of an end portion of the gate electrode 24 in the Z-direction may be changed. In the case where the end portion is in the position facing the p-type base region 20 in the X direction, even when the voltage is applied to the gate electrode 24, a channel is not formed only in the middle of the p-type base region 20, and a carrier is not capable of moving to the n⁻ type semiconductor region 12 from the n⁺ type source region 22. Accordingly, if the gate electrode 24 is formed so as to line up the position of the end portion in the Z direction with a position of a boundary between the n⁻ type semiconductor region 12 and the p-type source region 20 in the Z-direction, the possibility of generating an operation failure becomes high due to the manufacturing variation.

In the first embodiment, a portion of the gate electrode 24 is configured so as to face the n⁻ type semiconductor region 12 in the X direction, and thereby, even when the manufacturing variation is generated, it is possible to reduce the possibility of forming the end portion of the gate electrode 24 in a Z-direction at the position facing only the p-type base region 20 in the X direction.

Moreover, if a portion of the fourth insulating portion 26d is positioned between the p-type base region 20 and the gate electrode 24 in the X direction, when the channel is formed by applying the voltage to the gate electrode 24, the channel is deformed in the middle thereof. That is, the channel along the Z-direction which is formed in the vicinity of the third insulating portion 26c, and the channel along the direction inclined to the Z-direction which is formed in the vicinity of the fourth insulating portion 26d are formed.

Resistance with respect to the moving of the carrier in the channel is different according to the direction in which the channel extends. For example, when the plane orientation of the third surface S3 is (111), and the plane orientation of the fourth surface S4 is (100), the resistance of the channel which is formed in the vicinity of the fourth insulating portion 26d, is higher than the resistance of the channel which is formed in the vicinity of the third insulating portion 26c. Hence, if the variation in the depth of the n⁺ type source region 22, or the variation in the position of a lower end of the fourth insulating portion 26d, is generated, the variation is generated in the channel resistance between the semiconductor devices.

In contrast thereto, in the first embodiment, a portion of the third insulating portion 26c is positioned between the n⁺ type source region 22 and the gate electrode 24 in the X direction. By adopting the configuration described above, in the case of manufacturing the semiconductor device 100, for example, even when the variation is generated in the depth of the n⁺ type source region 22 or the shape of the trench Tr2, it is possible to reduce the possibility of arranging a portion of the fourth insulating portion 26d between the p-type base region 20 and the gate electrode 24 in the X direction. As a result, it is possible to suppress the variation in the channel resistance between the semiconductor devices.

Additionally, in the trench Tr2 where the gate electrode 24 and the gate insulating layer 26 are arranged, the dimension of the upper portion of the trench Tr2 in the X direction is greater than the dimension of the lower portion of the trench Tr2 in the X direction. As a result, in the gate electrode 24, the length of at least a portion of the second electrode portion 24b in the X direction is longer than the length of at least a portion of the first electrode portion 24a in the X direction.

The dimension of the upper portion of the trench Tr2 in the X direction is greater than the dimension of the lower portion of the trench Tr2 in the X direction, whereby it is possible to reduce the variation at the position where the trench Tr2 is formed. If the variation at the position of the trench Tr2 is reduced, it is possible to reduce a distance L1 (illustrated in FIG. 2) in the X direction between the end portion of the gate insulating layer 26 in the X direction, and the end portion of the gate electrode 24 in the X direction. By reducing the distance L1, it is possible to increase a contact area between the n⁺ type source region 22 and the source electrode 32, and it is possible to reduce the resistance of bonding between the n⁺ type source region 22 and the source electrode 32.

Moreover, by reducing the variation at the position of the trench Tr2, in the process of removing a portion of the gate insulating layer 26a and a portion of the insulating layer 28a illustrated in FIG. 7B, the possibility of incorrectly exposing the gate electrode 24, is reduced. Hence, it is possible to suppress the generation of a defective product to which the gate electrode 24 and the source electrode 32 are electrically connected, and it is possible to improve a yield rate in the manufacturing of the semiconductor device.

Furthermore, in the case where the dimension of the upper portion of the trench Tr2 in the X direction is greater than the dimension of the lower portion of the trench Tr2 in the X direction, it is possible to increase an angle α (illustrated in FIG. 2) of the angle portion of the opening end of the trench Tr2, in comparison with the case where the dimension of the upper portion of the trench Tr2 in the X direction is equal to the dimension of the lower portion of the trench Tr2 in the X direction. By increasing the angle α, when the gate insulating layer 26 is formed, the insulating layer may be formed to be thick along the angle portion. As a result, when the voltage is applied to the gate electrode 24, it is possible to reduce the possibility of generating the breakdown in the angle portion.

### Modification Example of First Embodiment

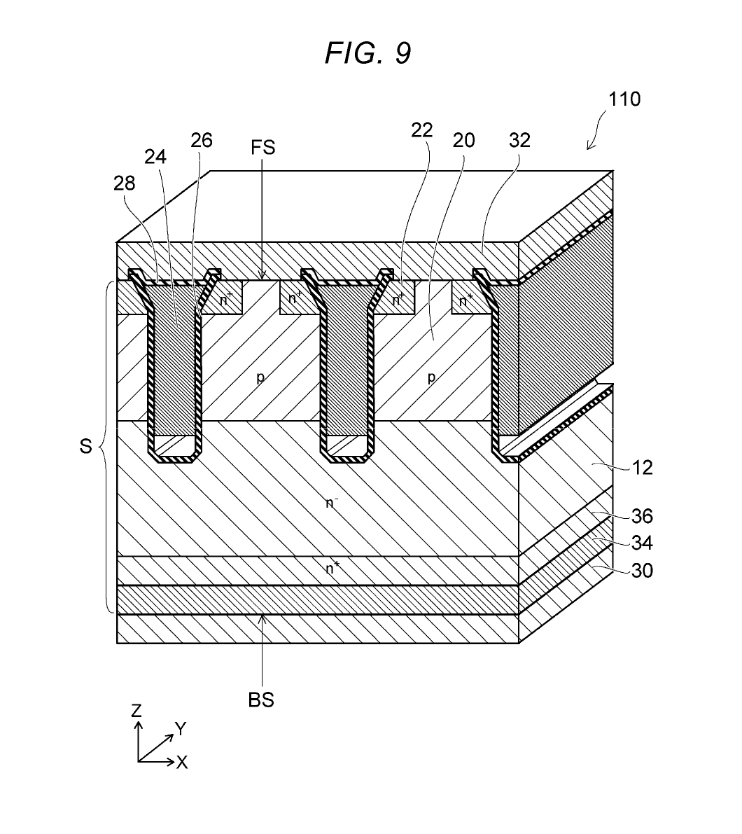

FIG. 9 is a perspective cross-sectional view illustrating a portion of a semiconductor device 110 according to a Modification Example of the first embodiment.

For example, the semiconductor device 110 is an IGBT (insulated gate bipolar transistor).

The semiconductor device 110 according to Modification Example, includes the semiconductor layer S, the gate electrode 24, the gate insulating layer 26 (first insulation layer), the insulating layer 28 (second insulating layer), an emitter electrode 32 (first electrode), and a collector electrode 30.

The semiconductor layer includes a p⁺ type collector region 34, an n⁺ type buffer region 36, the n⁺ type semiconductor region 12 (first semiconductor region), the p-type base region 20 (second semiconductor region), and the n⁺ type emitter region 22 (third semiconductor region).

For example, from a point that the p⁺ type collector region 34 and the n⁺ type buffer region 36 are included, instead of the n⁺ type drain region 10, the semiconductor device 110 is different from the semiconductor device 100. The structure other than the p⁺ type collector region 34 and the n⁺ type buffer region 36 in the semiconductor device 110 may adopt the same structure as the semiconductor device 100.

The p⁺ type collector region 34 is arranged on the back surface BS of the semiconductor layer S and is electrically connected to the collector electrode 30. The buffer region 36 is arranged between the collector region 34 and the n⁻ type semiconductor region 12.

The gate insulating layer 26 in the semiconductor device 110 includes the first insulating portion 26a to the fourth insulating portion 26d in the same manner as the first embodiment.

In Modification Example, when the voltage is applied to the gate electrode 24, it is possible to reduce the possibility of generating the breakdown in the gate insulating layer 26.

### Second Embodiment

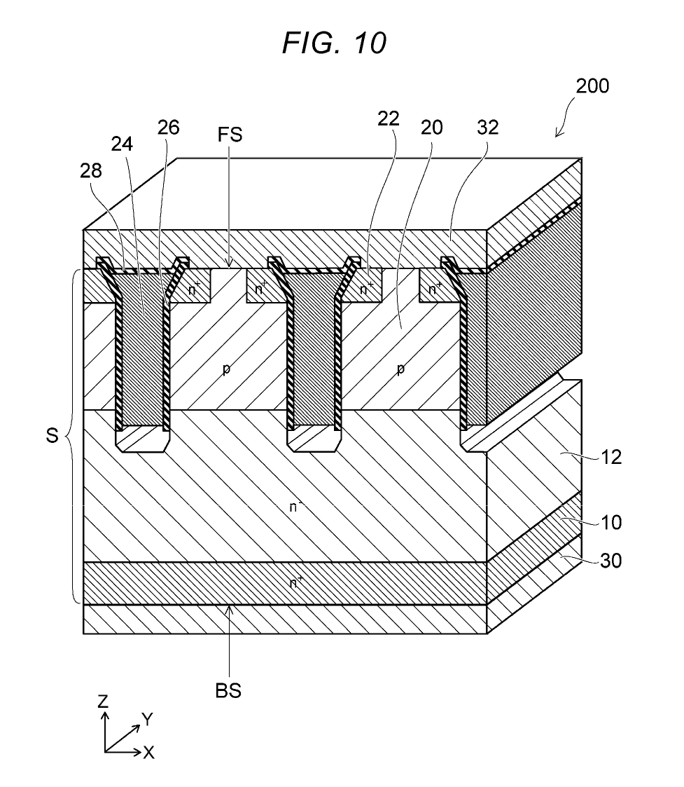

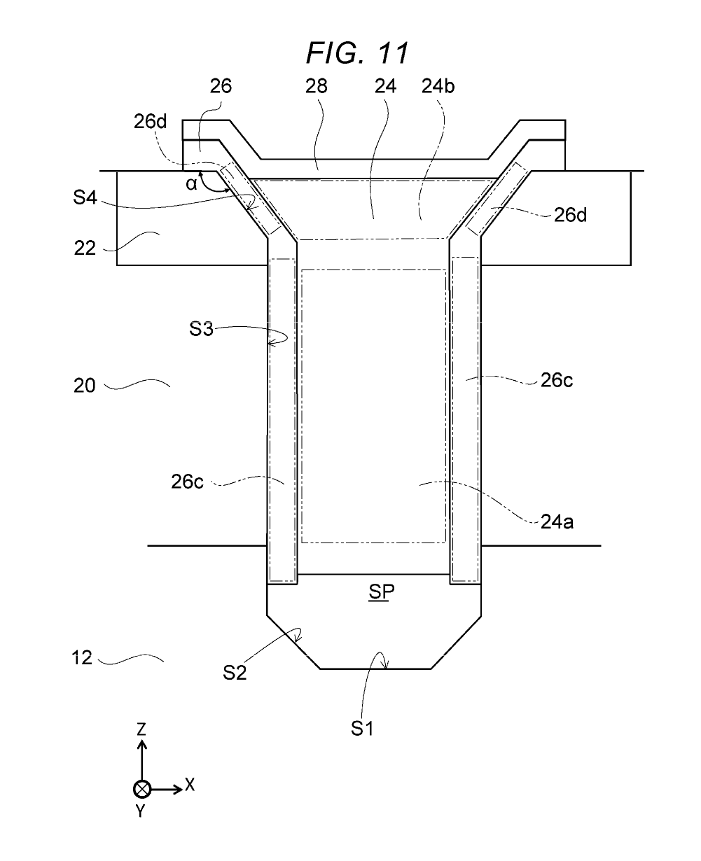

By using FIG. 10 and FIG. 11, a semiconductor device 200 according to a second embodiment will be described.

FIG. 10 is a perspective cross-sectional view illustrating a portion of the semiconductor device 200 according to the second embodiment.

FIG. 11 is an enlarged cross-sectional view illustrating a portion of the semiconductor device 200 according to the second embodiment.

For example, in the structure of the gate insulating layer 26, the semiconductor device 200 is different from the semiconductor device 100. The structure other than the gate insulating layer 26 in the semiconductor device 200, may adopt the same structure as that in the semiconductor device 100.

As illustrated in FIG. 11, the gate insulating layer 26 is not arranged in the bottom portion of the trench. That is, the gate insulating layer 26 does not include the first insulating portion 26a and the second insulating portion 26b, as illustrated in FIG. 2. In the Z direction, the gap SP is formed between the n⁻ type semiconductor region 12 and the gate electrode 24. In the Z-direction, the gap SP may be formed between the first insulating portion 36a and the n⁻ type semiconductor region 12. For example, the end portion of the Z-direction of the gate insulating layer 26 is positioned in the Z-direction side, with respect to the end portion of the Z-direction of the gate electrode 24.

In the second embodiment, the gate insulating layer and the gate electrode are not formed on the bottom surface of the trench which is formed in the semiconductor layer S. Hence, according to the second embodiment, it is possible to reduce the strength of the electrical field which is generated in the vicinity of the second surface S2. Therefore, when the voltage is applied to the gate electrode 24, it is possible to reduce the possibility of generating the breakdown in the gate insulating layer 26.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor region of a first conductivity type;
a second semiconductor region of a second conductivity type adjacent to the first semiconductor region in a first direction;
a third semiconductor region of the first conductivity type on the second semiconductor region and separated from the first semiconductor region in the first direction by the second semiconductor region; and
a gate electrode adjacent to the first, second, and third semiconductor regions, wherein
a gap is disposed between the gate electrode and the first semiconductor region.

2. The semiconductor device according to claim 1, wherein the gap is disposed between the gate electrode and the first semiconductor region along the first direction.

3. The semiconductor device according to claim 1, further comprising:
a first insulating layer between the gate electrode and the first semiconductor region, the gate electrode and the second semiconductor region, and the gate electrode and the third semiconductor region, the first insulating layer including:
a first portion on the first semiconductor region and extending along a second direction perpendicular to the first direction, the first portion being between the first semiconductor region and the gate electrode in the first direction, and
a second portion that is provided along a direction oblique to the first direction and the second direction, the second portion being between the first semiconductor region and the gate electrode.

4. The semiconductor device according to claim 3, wherein
a crystal plane orientation of a surface of the first semiconductor region in contact with the first portion is (111), and
a crystal plane orientation of a surface of the first semiconductor region in contact with the second portion is (100).

5. The semiconductor device according to claim 1, wherein
the gate electrode includes:
a first electrode portion facing the second semiconductor region in the second direction, and
a second electrode portion facing the third semiconductor region in a second direction perpendicular to the first direction, and
the second electrode portion is longer in the second direction than the first electrode portion in the second direction.

6. The semiconductor device according to claim 5, wherein
the first insulating layer further includes:
a third portion between the second semiconductor region and the first electrode portion, and
a fourth portion between the third semiconductor region and the second electrode portion and extending along a direction oblique to the first direction and the second direction, and
a portion of the third portion is between the third semiconductor region and the gate electrode in the second direction.

7. A semiconductor device, comprising:
a first semiconductor region of a first conductivity type;
a second semiconductor region of a second conductivity type adjacent to the first semiconductor region in a first direction;
a third semiconductor region of the first conductivity type on the second semiconductor region and separated from the first semiconductor region in the first direction by the second semiconductor region;
a gate electrode adjacent to the first, second, and third semiconductor regions; and
a first insulating layer between the gate electrode and the first semiconductor region, the gate electrode and the second semiconductor region, and the gate electrode and the third semiconductor region, the first insulating layer including:
a first portion on the first semiconductor region and extending along a second direction perpendicular to the first direction, the first portion being between the first semiconductor region and the gate electrode in the first direction, and
a second portion that is provided along a direction oblique to the first direction and the second direction, the second portion being between the first semiconductor region and the gate electrode, wherein
a gap is disposed between the gate electrode and the second portion.

8. The semiconductor device according to claim 7, wherein the gap is further disposed between the gate electrode and the first portion of the first insulating film in the first direction.

9. The semiconductor device according to claim 7, wherein
the gate electrode includes:
a first electrode portion facing the second semiconductor region in the second direction, and
a second electrode portion facing the third semiconductor region in the second direction, and
the second electrode portion is longer in the second direction than the first electrode portion in the second direction.

10. The semiconductor device according to claim 9, wherein
the first insulating layer further includes:
a third portion between the second semiconductor region and the first electrode portion and extending along the first direction, and
a fourth portion between the third semiconductor region and the second electrode portion and extending along a direction inclined with respect to the first direction and the second direction, and
a portion of the third insulating portion is between the third semiconductor region and the gate electrode in the second direction.

11. The semiconductor device according to claim 9, wherein
a crystal plane orientation of a surface of the first semiconductor region in contact with the first insulating portion is (111), and
a crystal plane orientation of a surface of the first semiconductor region in contact with the second insulating portion is (100).

12. The semiconductor device according to claim 9, further comprising:
a second insulating layer on the gate electrode and the third semiconductor region; and
a first electrode on the third semiconductor region and the second insulating layer, and electrically connected to the third semiconductor region.

13. The semiconductor device according to claim 9, wherein the gate electrode is a portion of an insulated gate bipolar transistor.

14. The semiconductor device according to claim 9, wherein the gate electrode is a portion of a metal-oxide-semiconductor field effect transistor.

15. The semiconductor device according to claim 9, wherein the first conductivity type is n-type and the second conductivity type is p-type.

16. A method of manufacturing a semiconductor device, comprising:
forming a trench extending into a semiconductor layer in a first direction, the trench having a first width at a surface of the semiconductor layer and a second width a first distance in the first direction from the surface, the trench having the second width along a first portion extending along the first direction and a third width that continuously decreases from the first width to the second width along a second portion extending along the first direction from the surface, the trench terminating in a first semiconductor region of a first conductivity type in the semiconductor layer;
forming an insulating film along sidewalls of the trench;
forming a conductive material on the insulating film formed along the sidewalls of the trench, such that a bottom portion of the trench that is adjacent to the first semiconductor region is not filled and a gap is left between the conductive material and the first semiconductor region;
forming a second semiconductor region of a second conductivity type in the semiconductor layer and on the first semiconductor region; and
forming a third semiconductor region of the first conductivity type in the semiconductor layer and on the second semiconductor region, the third semiconductor region being at the surface of the semiconductor layer.

17. The method of claim 16, wherein the conductive material comprises polysilicon deposited by a chemical vapor deposition method.

18. The method of claim 16, wherein the first portion of the trench is formed after the second portion of the trench.

19. The method of claim 16, wherein a crystal plane orientation at a bottom surface of the trench is (111) or (110), and a crystal plane orientation of an angled portion of a sidewall of the trench which meets the bottom surface is (100).

20. The method of claim 16, wherein a portion of the insulating film on a bottom surface of the trench and a portion of the insulating film on sidewalls adjacent to the bottom surface of the trench are removed before the conductive material is formed.
